(19) United States
(12) Patent Application Publication
(10) Pub. No.: US 2026/0052751 A1
(43) Pub. Date: Feb. 19, 2026

(54) FORMING SHARED SOURCE/DRAIN CONTACT WITH A GATE-CUT STRUCTURE

(71) Applicant: International Business Machines Corporation, Armonk, NY (US)

(72) Inventors: Chanro Park, Clifton Park, NY (US); Ruilong Xie, Niskayuna, NY (US); Min Gyu Sung, Latham, NY (US); Julien Frougier, Albany, NY (US); Juntao Li, Cohoes, NY (US)

(21) Appl. No.: 18/807,064

(22) Filed: Aug. 16, 2024

(51) Int. Cl. H01L 29/417; H01L 21/28; H01L 21/8234; H01L 27/088; H01L 29/06; H01L 29/423; H01L 29/66; H01L 29/775; H01L 29/786

(52) U.S. Cl. CPC H10D 64/259; H01L 21/28; H10D 84/0135; H10D 84/038; H10D 84/83; H10D 30/014; H10D 30/43; H10D 30/6735; H10D 30/6757; H10D 62/121

(57) ABSTRACT

Embodiments of present invention provide a semiconductor structure. The semiconductor structure includes a first and a second nanosheet (NS) transistor on top of a semiconductor substrate; a shared source/drain (S/D) contact surrounding a first S/D region of the first NS transistor and a second S/D region of the second NS transistor; and a gate-cut structure isolating a first metal gate of the first NS transistor from a second metal gate of the second NS transistor, where a portion of the gate-cut structure is surrounded by the shared S/D contact at a top and sidewalls of the gate-cut structure. A method of forming the same is also provided.

### BACKGROUND

The present application relates to manufacturing of semiconductor integrated circuits. More particularly, it relates to method of forming shared source/drain contact with a gate-cut structure and the structure formed thereby.

A semiconductor system derives its basic functions from various semiconductor devices that the system contains. Various semiconductor devices are built from a fundamental building block that is knows as a complementary metal-oxide semiconductor field-effect-transistor (CMOS-FET), or commonly known as a transistor. There are various types of transistors such as, for example, planar transistors, fin-type transistors (FinFET), nanosheet (NS) transistors, vertical transistors, and gate-all-around (GAA) transistors, to list a few. A semiconductor chip may contain many such as thousands of transistors that are formed on a semiconductor substrate.

In forming transistors, a replacement-metal-gate (RMG) process may be used which is then followed by a gate-cut process. The gate-cut process may first remove a portion of the gate stack formed by the RMG process and a portion of an interlevel dielectric layer between transistors to create a gate-cut opening. A dielectric material is then deposited to fill the gate-cut opening to form a gate-cut structure. After forming the gate-cut structure, a shared source/drain contact across the gate-cut structure may be formed. A selective source/drain contact etch process is generally used in forming the shared source/drain contact. However, with the dielectric material such as silicon-nitride being used for the gate-cut structure, it becomes increasingly difficult to use the selective etch process to form the shared source/drain contact.

### SUMMARY

Embodiments of present invention provide a semiconductor structure. The semiconductor structure includes a first and a second nanosheet (NS) transistor on top of a semiconductor substrate; a shared source/drain (S/D) contact surrounding a first S/D region of the first NS transistor and a second S/D region of the second NS transistor; and a gate-cut structure isolating a first metal gate of the first NS transistor from a second metal gate of the second NS transistor, where a portion of the gate-cut structure is surrounded by the shared S/D contact at a top and sidewalls of the gate-cut structure.

In one embodiment, the portion of the gate-cut structure is horizontally between the first S/D region of the first NS transistor and the second S/D region of the second NS transistor.

In another embodiment, a first portion of the shared S/D contact at a first side of the gate-cut structure is self-aligned to a first sidewall spacer of the first metal gate of the first NS transistor, and a second portion of the shared S/D contact at a second side of the gate-cut structure is self-aligned to a second sidewall spacer of the second metal gate of the second NS transistor.

In yet another embodiment, a third portion of the shared S/D contact directly above the gate-cut structure is formed in a recess of the gate-cut structure and a width of the recess, in a direction along a length of the first metal gate, is wider than a width of the first portion of the shared S/D contact, in the direction along the length of the first metal gate.

In one embodiment, a bottom surface of the recess of the gate-cut structure is at a level above a top surface of the first and the second S/D region of the first and the second NS transistor.

In another embodiment, the gate-cut structure and the first and the second sidewall spacer are made of a same dielectric material of silicon-nitride (SiN).

In yet another embodiment, the shared S/D contact substantially surrounds the first and the second S/D region at a top and sidewalls thereof.

Embodiments of present invention provide a method of forming a semiconductor structure. The method includes forming a first and a second nanosheet (NS) transistor on a substrate; forming a gate-cut structure isolating a first metal gate of the first NS transistor from a second metal gate of the second NS transistor; removing an interlevel-dielectric (ILD) layer that covers a first source/drain (S/D) region of the first NS transistor and a second S/D region of the second NS transistor to create a first and a second contact opening; removing a portion of the gate-cut structure in a region between the first and the second contact opening to create a recess; and filling the first and the second contact opening and the recess with a conductive material to form a shared S/D contact.

In one embodiment, removing the portion of the gate-cut structure includes forming a dielectric liner lining sidewalls of the first and the second contact opening, thereby covering a first and a second sidewall spacer of the first and the second metal gate respectively of the first and the second NS transistor, the dielectric liner covering sidewalls of the gate-cut structure in the region between the first and the second contact opening, the dielectric liner having a material that has an etch selectivity different from that of the first and the second sidewall spacer and the gate-cut structure; selectively etching the gate-cut structure in the region from a top thereof, relative to the dielectric liner and the first and the second S/D region, to create the recess; and removing the dielectric liner.

In another embodiment, the gate-cut structure and the sidewall spacers of the first and the second metal gate of the first and the second NS transistor are made of silicon-nitride and the dielectric liner is made of silicon-oxide.

In yet another embodiment, removing the ILD layer includes forming a contact mask covering the first metal gate of the first NS transistor and the second metal gate of the second NS transistor, the contact mask having a mask opening over the first and the second S/D region and a portion of the gate-cut structure; and selectively removing the ILD layer, relative to the first and the second S/D region and the gate-cut structure, to create the first and the second contact opening.

According to one embodiment, the sidewall spacers of the first and the second metal gate of the first and the second NS transistor are made of silicon-nitride, and the method further includes forming a capping layer of silicon-oxide on top of the first and the second metal gate of the first and the second NS transistor before forming the contact mask on top of the capping layer.

In one embodiment, forming the gate-cut structure includes forming the gate-cut structure across multiple sets of NS transistors including a first set of the first and the second NS transistor and a second set of a third and a fourth NS transistor, and across a region between the first and the second S/D region of the first and the second NS transistor.

In another embodiment, the mask opening is wider than a length of the first S/D region of the first NS transistor, in a direction along a length of the first metal gate, and the first contact opening being self-aligned to the first sidewall spacer of the first metal gate.

Embodiments of present invention further provide a semiconductor structure, which includes a first set of nanosheet (NS) transistors including a first and a second NS transistor; a second set of NS transistors including a third and a fourth NS transistor; a shared source/drain (S/D) contact surrounding a first S/D region of the first NS transistor and a second S/D region of the second NS transistor; and a gate-cut structure isolating a first metal gate of the first NS transistor from a second metal gate of the second NS transistor and isolating a third metal gate of the third NS transistor from a fourth metal gate of the fourth NS transistor, where a portion of the gate-cut structure is surrounded by the shared S/D contact at a top and sidewalls of the gate-cut structure.

In one embodiment, the portion of the gate-cut structure is horizontally between the first S/D region of the first NS transistor and the second S/D region of the second NS transistor.

In another embodiment, a first portion of the shared S/D contact at a first side of the gate-cut structure is self-aligned to a first and a third sidewall spacer of the first and the third metal gate of the first and the third NS transistor respectively; and a second portion of the shared S/D contact at a second side of the gate-cut structure is self-aligned to a second and a fourth sidewall spacer of the second and the fourth metal gate of the second and the fourth NS transistor respectively.

In yet another embodiment, a third portion of the shared S/D contact directly above the gate-cut structure is formed in a recess of the gate-cut structure and a width of the recess is larger than a width of the first portion of the shared S/D contact between the first and the third sidewall spacer of the first and the third NS transistor.

In one embodiment, a bottom surface of the recess of the gate-cut structure is above a top surface of the first and the second S/D region of the first and the second NS transistor.

In another embodiment, the gate-cut structure and the first and the second sidewall spacers are made of silicon-nitride (SiN).

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, 1C, and 1D to FIGS. 11A, 11B, 11C, and 11D are demonstrative illustrations of cross-sectional views and FIG. 1E to FIG. 11E are simplified top views of a semiconductor structure at various steps of manufacturing thereof according to one embodiment of present invention; and

FIG. 12 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

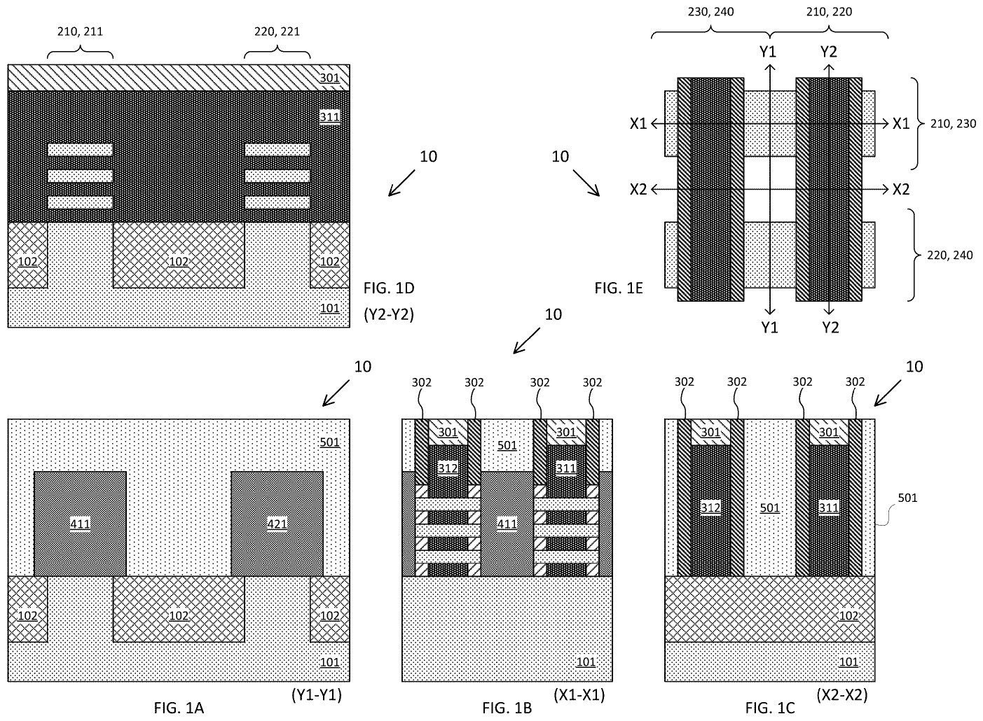

FIGS. 1A, 1B, 1C, and 1D are demonstrative illustrations of different cross-sectional views and FIG. 1E is a simplified top view of a semiconductor structure 10 in a step of manufacturing thereof according to one embodiment of present invention. More specifically, FIG. 1A illustrates a cross-sectional view of the semiconductor structure 10 with a cross-section made along a line Y1-Y1 as illustrated in FIG. 1E. In other words, the cross-section in FIG. 1A is made across the source/drain region in a direction along the width of the gate. FIG. 1B illustrates a cross-sectional view of the semiconductor structure 10 with a cross-section made along a line X1-X1 as illustrated in FIG. 1E. In other words, the cross-section in FIG. 1B is made across the gate and the source/drain region in a direction along the length of the gate. FIG. 1C illustrates a cross-sectional view of the semiconductor structure 10 with a cross-section made along a line X2-X2 as illustrated in FIG. 1E. In other words, the cross-section in FIG. 1C is made outside the source/drain region in a direction along the length of the gate. FIG. 1D illustrates a cross-sectional view of the semiconductor structure 10 with a cross-section made along a line Y2-Y2 as illustrated in FIG. 1E. In other words, the cross-section in FIG. 1D is made across the gate in a direction along the width of the gate.

As its purpose is to show locations of the cross-sections illustrated in FIGS. 1A, 1B, 1C, and 1D, the simplified top view of FIG. 1E may selectively illustrate only key features such as, for example, nanosheets, gates, source/drain regions, and sidewall spacers that were previously formed, are yet to be formed or whose views may be obscured by other elements. Features such as interlevel dielectric layers surrounding the above structures, dielectric caps, photomasks, etc. may not necessarily be illustrated in order not to overcrowd FIG. 1E, and to the extent that their omission from FIG. 1E does not hinder the description of embodiments of present invention, which are mainly provided hereinafter with reference to FIGS. 1A, 1B, 1C and 1D.

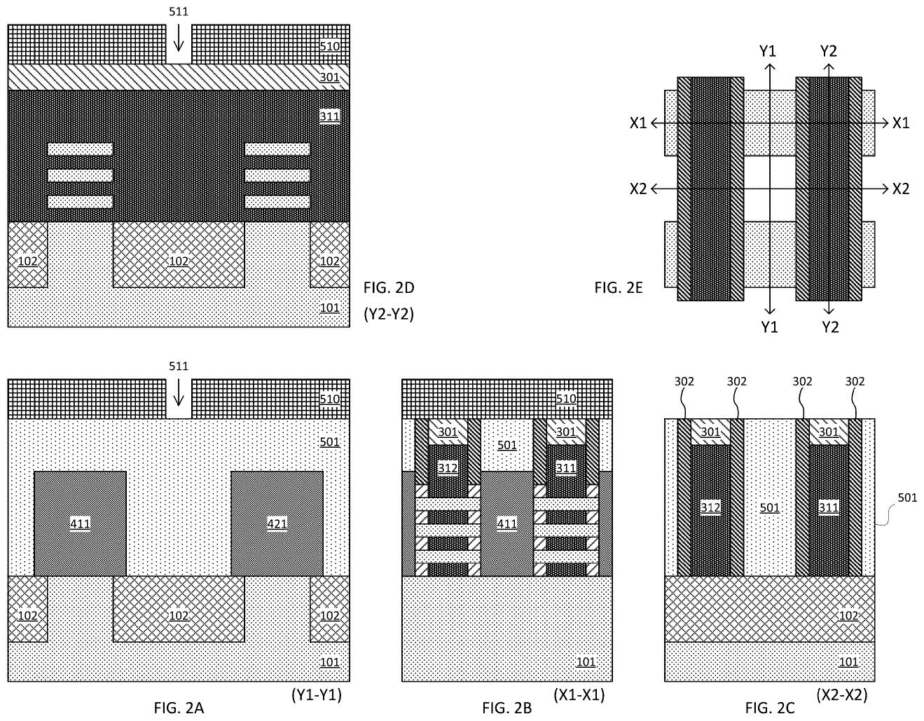

Likewise, FIGS. 2A, 2B, 2C, and 2D to FIGS. 11A, 11B, 11C, and 11D are demonstrative cross-sectional views and FIG. 2E to FIG. 11E are simplified top views of a semiconductor structure of the same or different embodiments, at different manufacturing steps, illustrated in manners similar to FIGS. 1A, 1B, 1C, 1D, and 1E respectively.

Embodiments of present invention provide receiving or forming a semiconductor structure 10 that is demonstratively illustrated to include one or more sets of nanosheet (NS) transistors such as a first set of NS transistors and a second set of NS transistors. For example, the first set of NS transistors may include a first NS transistor 210 and a second NS transistor 220 and the second set of NS transistors may include a third NS transistor 230 and a fourth NS transistor 240. It is to be noted here that embodiments of present invention are not limited in this aspect and may be applied to other types of transistors and/or active devices as well. The one or more sets of NS transistors may be formed on top of a semiconductor substrate 101, and one or more shallow-trench-isolation (STI) structures 102 may be formed to be embedded in the semiconductor substrate 101 and between the NS transistors of the one or more sets of NS transistors such as, for example, between the first and the second NS transistor 210 and 220, and between the third and the fourth NS transistor 230 and 240.

The semiconductor substrate 101 may be a silicon (Si) substrate, a silicon-germanium (SiGe) substrate, a silicon-on-insulator (SOI) substrate, a silicon-germanium-on-insulator (SiGeOI) substrate, or other suitable substrates. The one or more STI structures 102 may be one or more layers of dielectric materials and the dielectric materials may include, for example, silicon-oxide (SiOx), silicon-nitride (SiN), silicon-carbide (SiC), silicoboron-carbonitride (SiBCN), silicon-oxycarbide (SiOC), silicon-oxycarbonitride (SiOCN), or other suitable dielectric materials.

The first and the second NS transistor 210 and 220 may each include a set of channel sheets 211 and 221, respectively, that are surrounded by a first raw metal gate 311 (see FIG. 1D). The third and the fourth NS transistor 230 and 240 may each include a set of channel sheets as well that are surrounded by a second raw metal gate 312. A metal gate, such as the first and the second raw metal gate 311 and 312, may include a gate dielectric layer, one or more work-function-metal (WFM) layers, and one or more layers of conductive material surrounding the WFM layers. The conductive material may include, for example, tungsten (W), aluminum (Al), cobalt (Co), ruthenium (Ru), or other conductive material. A dielectric cap 301 may be formed on top of the first and the second raw metal gate 311 and 312. Sidewall spacers 302 may be formed at sidewalls of the first and the second raw metal gate 311 and 312.

In one embodiment, material of the sidewall spacers 302 may be silicon-nitride (SiN). However, embodiments of present invention are not limited in this aspect and the sidewall spacers 302 may include SiOx, SiC, SiBCN, SiOC, SiOCN, or other suitable dielectric material as well. Source/drain (S/D) regions may be epitaxially formed, for example between the first and the second set of NS transistors, from end surfaces of the set of channel sheets 211 and 221. For example, a first S/D region 411 may be formed for the first NS transistor 210 and a second S/D region 421 may be formed for the second NS transistor 220. An interlevel-dielectric (ILD) layer 501 may be formed on top of and/or surrounding the first and the second S/D region 411 and 421 and in-between the first and the second raw metal gate 311 and 312 of the first and the second set of NS transistors (see FIG. 1C). Material of the ILD layer 501 may have an etch selectivity different from that of the sidewall spacers 302 and in one embodiment may be silicon-oxide (SiOx). However, in other embodiments material of the ILD layer 501 may be SiN, SiC, SiBCN, SiOC, SiOCN, or other suitable dielectric material with an etch selectivity that is different from the sidewall spacers 302 as well. The ILD layer 501 may be planarized to be coplanar with the dielectric cap 301. In one embodiment, material of the dielectric cap 301 may be SiN to be the same as the sidewall spacer 302.

FIGS. 2A, 2B, 2C, and 2D are demonstrative illustrations of different cross-sectional views and FIG. 2E is a simplified top view of the semiconductor structure 10 in a step of manufacturing thereof according to one embodiment of present invention. More specifically, following the step illustrated in FIGS. 1A, 1B, 1C, 1D, and 1E, embodiments of present invention provide forming a gate-cut mask 510 on top of the first and the second set of NS transistors. The gate-cut mask 510 may be a photo-resist mask stack and may be formed, for example, through a lithographic patterning process to include one or more openings such as an opening 511 that is formed horizontally between active channels and between S/D regions of the NS transistors such as between the first S/D region 411 of the first NS transistor 210 and the second S/D region 421 of the second NS transistor 220. The opening 511 may be formed to have a direction or orientation that is perpendicular to a width direction of the first and the second raw metal gate 311 and 312.

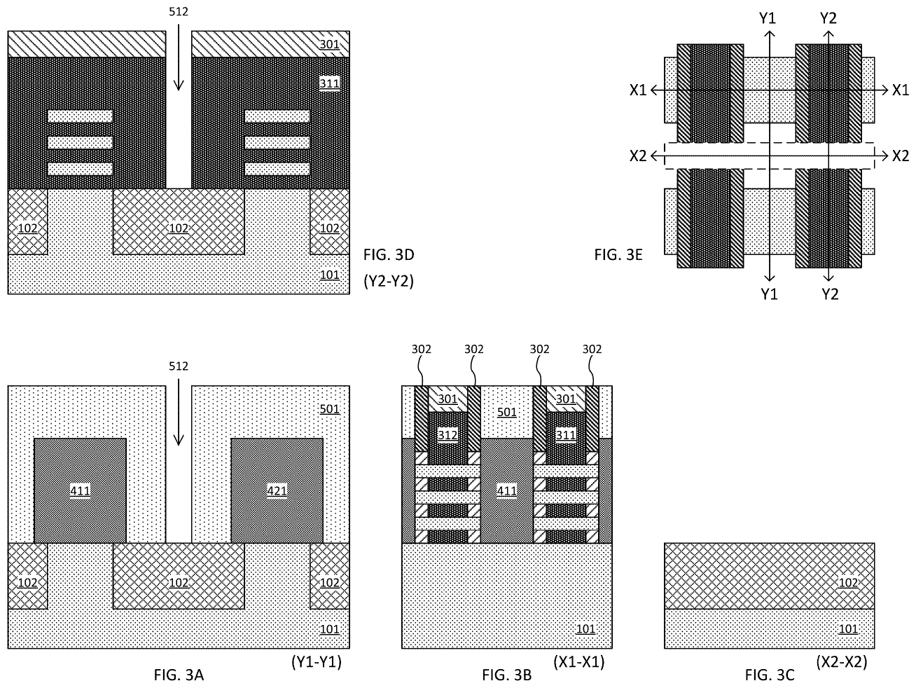

FIGS. 3A, 3B, 3C, and 3D are demonstrative illustrations of different cross-sectional views and FIG. 3E is a simplified top view of the semiconductor structure 10 in a step of manufacturing thereof according to one embodiment of present invention. More specifically, following the step illustrated in FIGS. 2A, 2B, 2C, 2D, and 2E, embodiments of present invention provide transferring the pattern of the gate-cut mask 510, in particular the opening 511, onto the first and the second raw metal gate 311 and 312 and the ILD layer 501 underneath the gate-cut mask 510. The transferring may be made through a selective etch process and may thus create a gate-cut opening 512. The gate-cut opening 512 may divide the first raw metal gate 311 into individual metal gates of the first and the second NS transistor 210 and 220 respectively and divide the second raw metal gate 312 into individual metal gates of the third and the fourth NS transistor 230 and 240 respectively. After the creation of the gate-cut opening 512, the gate-cut mask 510 may be removed through, for example, an ash process or other wet etch process.

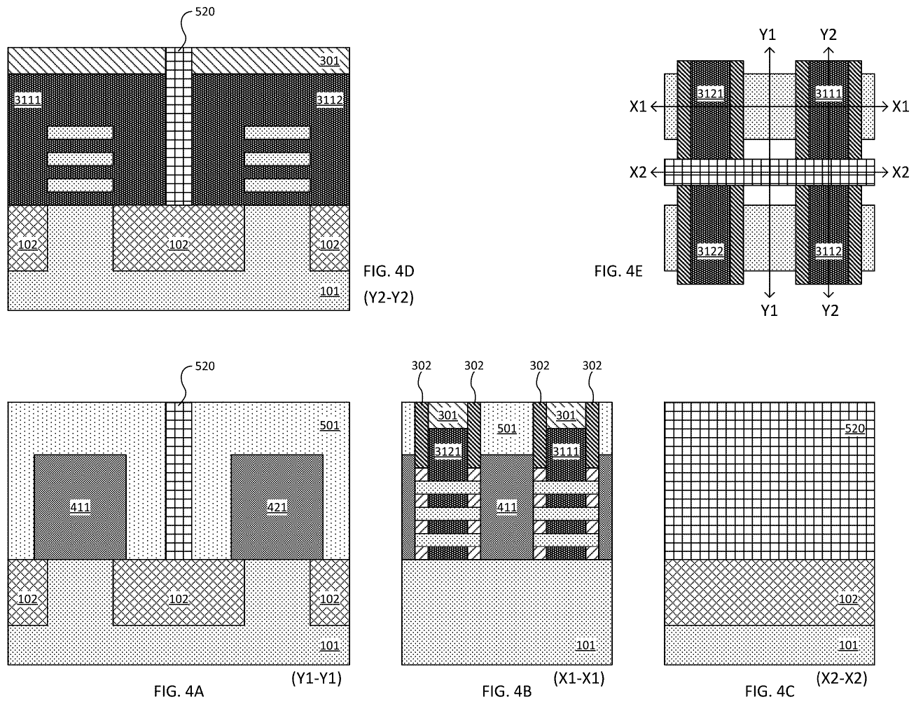

FIGS. 4A, 4B, 4C, and 4D are demonstrative illustrations of different cross-sectional views and FIG. 4E is a simplified top view of the semiconductor structure 10 in a step of manufacturing thereof according to one embodiment of present invention. More specifically, following the step illustrated in FIGS. 3A, 3B, 3C, 3D, and 3E, embodiments of present invention provide filling the gate-cut opening 512 with a dielectric material to form a gate-cut structure 520. The gate-cut structure 520 may be formed sufficiently deep to reach the STI structure 102 and completely cut or divide the first raw metal gate 311 into a first metal gate 3111 and a second metal gate 3112 of the first and the second NS transistor 210 and 220; and cut or divide the second raw metal gate 312 into a third metal gate 3121 and a fourth metal gate 3122 of the third and the fourth NS transistor 230 and 240. The gate-cut structure 520 thus may separate and isolate the first metal gate 3111 of the first NS transistor 210 from the second metal gate 3112 of the second NS transistor 220 and separate and isolate the third metal gate 3121 of the third NS transistor 230 from the fourth metal gate 3122 of the fourth NS transistor 240.

Material of the gate-cut structure 520 may have an etch selectivity that is substantially same as that of the sidewall spacers 302 but different from that of the ILD layer 501. For example, in one embodiment material of the gate-cut structure 520 and the sidewall spacers 302 may be a same material of silicon-nitride (SiN) and may be different from the ILD layer 501 of silicon-oxide (SiOx). However, embodiments of present invention are not limited in this aspect and material of the gate-cut structure 520 may be SiOx, SiC, SiBCN, SiOC, SiOCN, or other suitable dielectric material but still have an etch selectivity that is substantially same as that of the sidewall spacers 302 as well, but different from that of the ILD layer 501.

After filling the gate-cut opening 512 with the dielectric material, such as through a chemical-vapor-deposition (CVD) process, a physical-vapor-deposition (PVD) process, or an atomic-layer-deposition (ALD) process, a chemical-mechanical-polishing (CMP) process may be applied to planarize a top surface of the gate-cut structure 520 to be coplanar with a top surface of the ILD layer 501 and the dielectric cap 301.

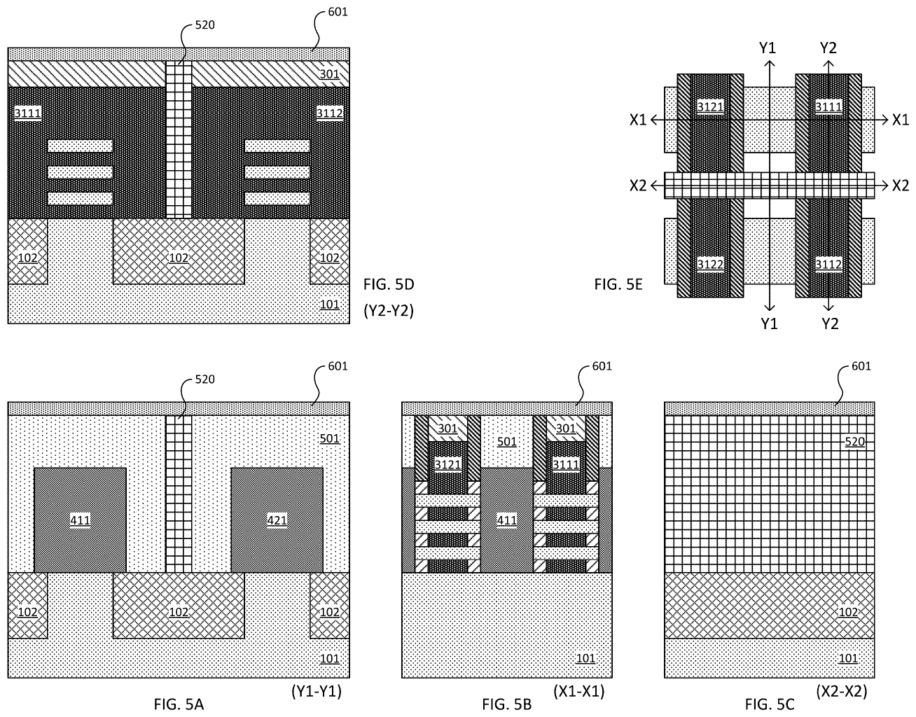

FIGS. 5A, 5B, 5C, and 5D are demonstrative illustrations of different cross-sectional views and FIG. 5E is a simplified top view of the semiconductor structure 10 in a step of manufacturing thereof according to one embodiment of present invention. More specifically, following the step illustrated in FIGS. 4A, 4B, 4C, 4D, and 4E, embodiments of present invention provide forming a capping layer 601 on top of the ILD layer 501, the first and the second set of NS transistors, and the gate-cut structure 520. The capping layer 601 may be made of a dielectric material, such as a silicon-oxide (SiOx), having an etch selectivity different from that of the gate-cut structure 520; and may be formed through a deposition process such as a CVD process, a PVD process, or an ALD process. The capping layer 601 may be formed to have a thickness ranging from about 5 nm to about 30 nm. The capping layer 601 may be formed to help prevent unexpected shorting and improve process margins.

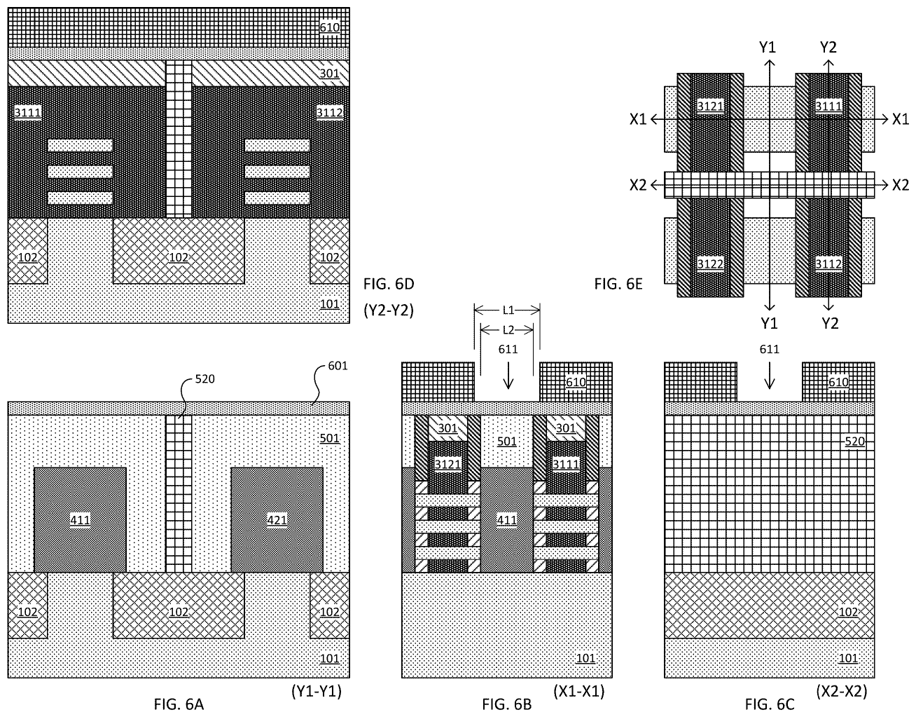

FIGS. 6A, 6B, 6C, and 6D are demonstrative illustrations of different cross-sectional views and FIG. 6E is a simplified top view of the semiconductor structure 10 in a step of manufacturing thereof according to one embodiment of present invention. More specifically, following the step illustrated in FIGS. 5A, 5B, 5C, 5D, and 5E, embodiments of present invention provide forming a contact mask 610 on top of the capping layer 601. The contact mask 610 may have one or more mask openings such a mask opening 611 that is substantially aligned with the first and the second S/D region 411 and 421 along a width direction of the first and the second metal gate 3111 and 3112 of the first and the second NS transistor 210 and 220; and perpendicular to the gate-cut structure 520. The contact mask 610 may be formed through a lithographic patterning process, and the mask opening 611 may have a width L1, measured along a length direction of the first metal gate 3111, that is equal to or wider than a gap between sidewall spacers 302 of the first and the third metal gate 3111 and 3121 of the first and the third NS transistor 210 and 230. In other words, the width L1 of the mask opening 611 may be equal to or wider than a length L2 of the first S/D region 411, measured along a length direction of the first metal gate 3111, between the sidewall spacers 302 of the first and the third metal gate 3111 and 3121 of the first and the third NS transistor 210 and 230.

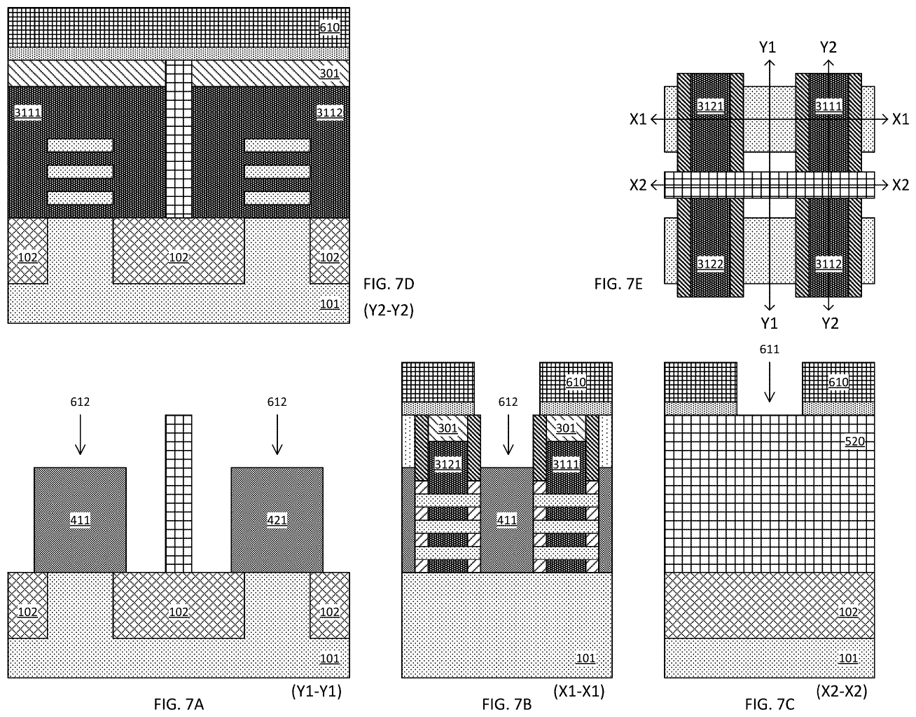

FIGS. 7A, 7B, 7C, and 7D are demonstrative illustrations of different cross-sectional views and FIG. 7E is a simplified top view of the semiconductor structure 10 in a step of manufacturing thereof according to one embodiment of present invention. More specifically, following the step illustrated in FIGS. 6A, 6B, 6C, 6D, and 6E, embodiments of present invention provide selectively etching the ILD layer 501 in-between the sidewall spacers 302 of the first and the third metal gate 3111 and 3121 and in-between the sidewall spacers 302 of the second and the fourth metal gate 3112 and 3122 thereby creating a first and a second opening 612 between the sidewall spacers 302. The openings 612 expose the first and the second S/D region 411 and 421 between the first and the third metal gate 3111 and 3121 and between the second and the fourth metal gate 3112 and 3122 respectively. The openings 612 may substantially expose both top surfaces and sidewall surfaces of the first and the second S/D region 411 and 421 until the STI structure 102 are exposed. The etch process may etch the ILD layer 501, which is for example silicon-oxide, selective to the sidewall spacers 302 and the gate-cut structure 520, both of which are silicon-nitride. The etch process is also selective to the first and the second S/D region 411 and 421 that may be epitaxially grown Si or SiGe.

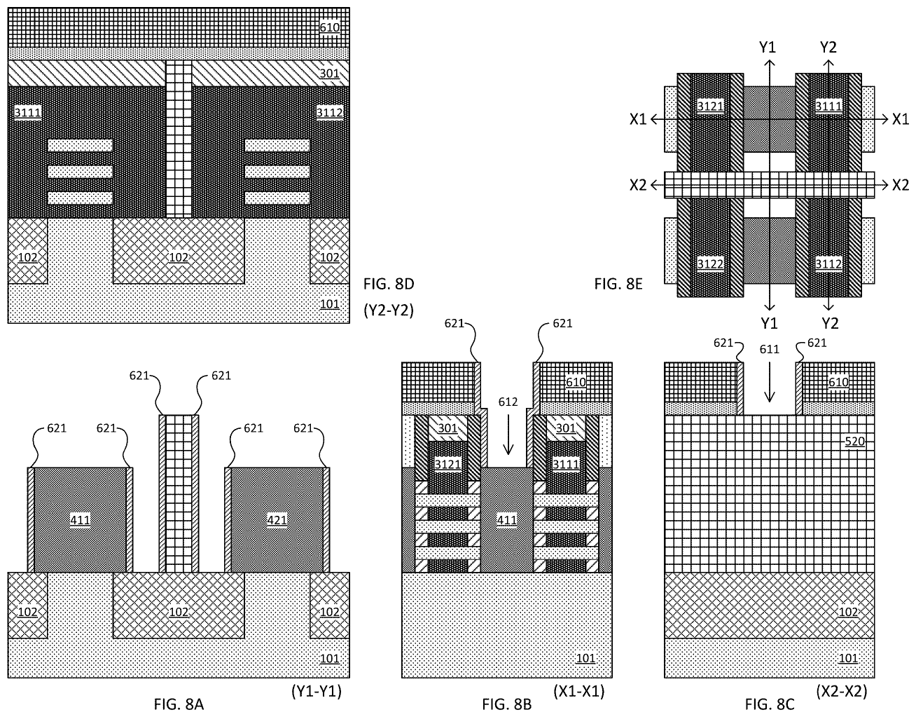

FIGS. 8A, 8B, 8C, and 8D are demonstrative illustrations of different cross-sectional views and FIG. 8E is a simplified top view of the semiconductor structure 10 in a step of manufacturing thereof according to one embodiment of present invention. More specifically, following the step illustrated in FIGS. 7A, 7B, 7C, 7D, and 7E, embodiments of present invention provide forming a dielectric liner 621 lining sidewalls of the sidewall spacers 302 and sidewalls of the gate-cut structure 520; and sidewalls of the first and the second S/D region 411 and 421. For example, in forming the dielectric liner 621, a dielectric layer of, for example, silicon-oxide (SiOx) may be conformally deposited covering both bottom and sidewall surfaces of the mask opening 611 and the openings 612. A directional and/or anisotropic etch process may subsequently be applied to remove horizontal portions of the dielectric layer thereby causing the vertical portions of the dielectric layer to remain at vertical surfaces of the mask opening 611 and the openings 612 to become dielectric liner 621. Material of the dielectric liner 621 may be selected such that it has an etch selectivity different from that of the gate-cut structure 520. For example, material of the dielectric liner 621 may be silicon-oxide (SiOx) when the gate-cut structure 520, as well as the sidewall spacers 302, is made of silicon-nitride (SiN).

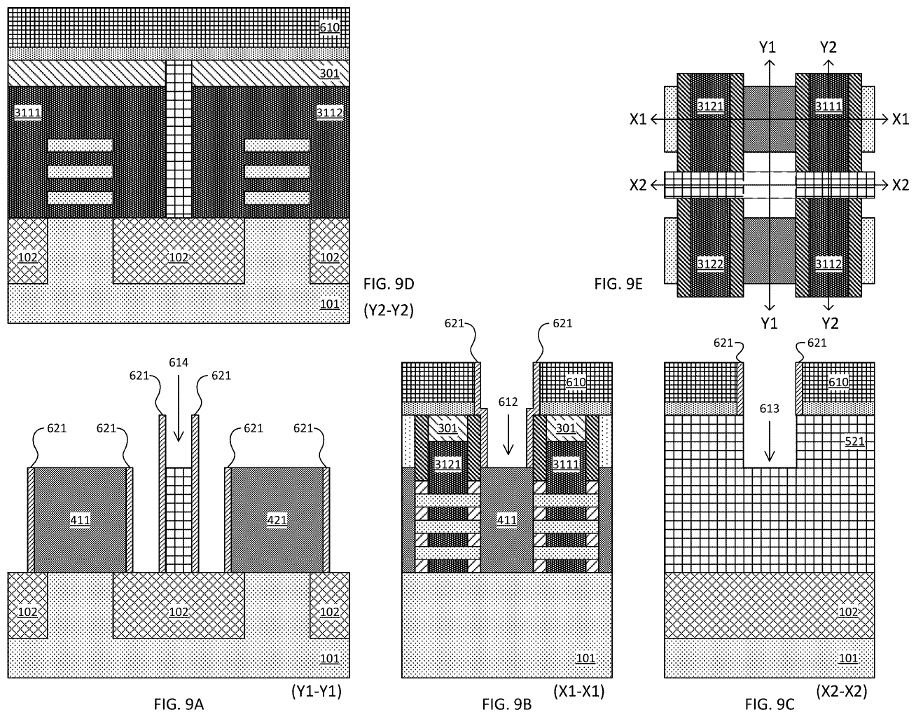

FIGS. 9A, 9B, 9C, and 9D are demonstrative illustrations of different cross-sectional views and FIG. 9E is a simplified top view of the semiconductor structure 10 in a step of manufacturing thereof according to one embodiment of present invention. More specifically, following the step illustrated in FIGS. 8A, 8B, 8C, 8D, and 8E, embodiments of present invention provide selectively etch the gate-cut structure 520, in the region between the first and the second opening 612, to create a recess 613 in the gate-cut structure 520. In one embodiment, the recess 613 created by the selective etch process may have a bottom surface at a level that is at or above the top surfaces of the first and the second S/D region 411 and 421. In other words, the bottom surface of the recess 613 may have a height, measured from a top surface of the substrate 101 or the STI structure 102, that is equal to or higher than the top surfaces of the first and the second S/D region 411 and 421. The recess 613 may also have a width, measured along a length direction of the metal gates such as the first metal gate 3111, that is equal to or wider than a width of the openings 612.

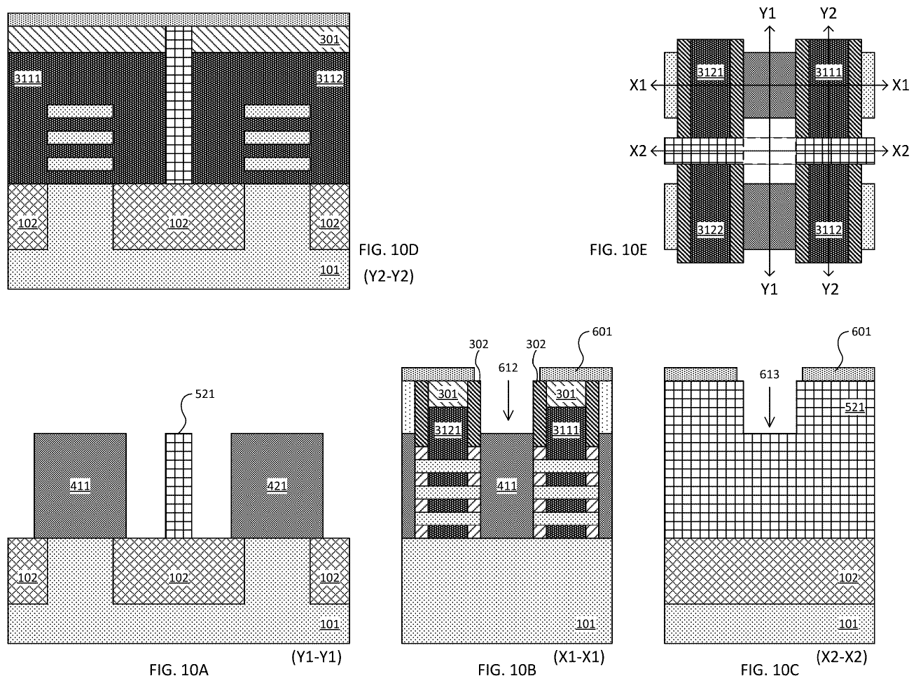

FIGS. 10A, 10B, 10C, and 10D are demonstrative illustrations of different cross-sectional views and FIG. 10E is a simplified top view of the semiconductor structure 10 in a step of manufacturing thereof according to one embodiment of present invention. More specifically, following the step illustrated in FIGS. 9A, 9B, 9C, 9D, and 9E, embodiments of present invention provide removing the dielectric liner 621, in a selective etch process, from sidewalls of the sidewall spacers 302 and sidewalls of the gate-cut structure 520. The selective etch process re-exposes the first and the second S/D region 411 and 421 for forming S/D contact in contact therewith.

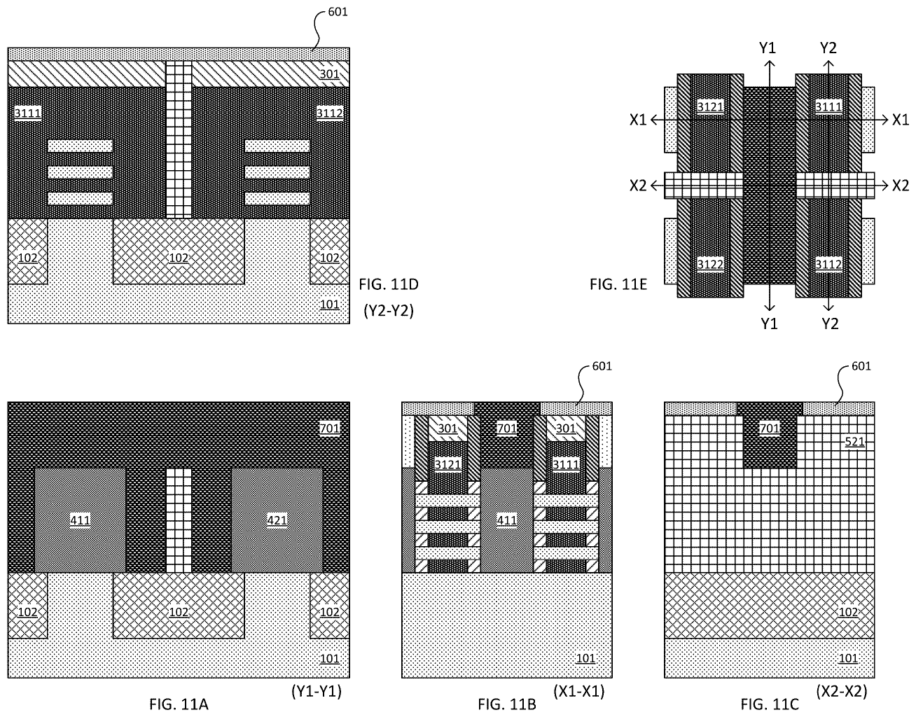

FIGS. 11A, 11B, 11C, and 11D are demonstrative illustrations of different cross-sectional views and FIG. 11E is a simplified top view of the semiconductor structure 10 in a step of manufacturing thereof according to one embodiment of present invention. More specifically, following the step illustrated in FIGS. 10A, 10B, 10C, 10D, and 10E, embodiments of present invention provide filling the recess 613 and the first and the second opening 612, between the first and the third metal gate 3111 and 3121 of the first and the third NS transistor 210 and 230 and between the second and the fourth metal gate 3112 and 3122 of the second and the fourth NS transistor 220 and 240, with a conductive material to form a shared S/D contact 701. The shared S/D contact 701 may be shared by the first S/D region 411 of the first NS transistor 210 and the second S/D region 421 of the second NS transistor 220. The conductive material of the shared S/D contact 701 may be tungsten (W), aluminum (Al), cobalt (Co), ruthenium (Ru), copper (Cu) or other suitable conductive materials. Filling the recess 613 and the first and the second opening 612 may be made through a deposition process such as a CVD process, a PVD process, or an ALD process, or through a metal plating process. A CMP process may subsequently be applied to planarize a top surface of the shared S/D contact 701 such that it becomes coplanar with a top surface of the capping layer 601.

In one embodiment, a portion of the shared S/D contact 701 formed directly above the gate-cut structure 520 in the recess 613 may have a width that is equal to or larger than a width of the shared S/D contact 701 formed in between the first and the third metal gate 3111 and 3121 of the first and the third NS transistor 210 and 230 or between the second and the fourth metal gate 3112 and 3122 of the second and the fourth NS transistor 220 and 240.

In one embodiment, a first portion of the shared S/D contact 701 at a first side, such as a left-side as in FIGS. 11A and 11D, of the gate-cut structure 520 is self-aligned to a sidewall spacer 302 of the first metal gate 3111 of the first NS transistor 210, and a second portion of the shared S/D contact 701 at a second side, such as a right-side as in FIGS. 11A and 11D, of the gate-cut structure 520 is self-aligned to a sidewall spacer 302 of the second metal gate 3112 of the second NS transistor 220.

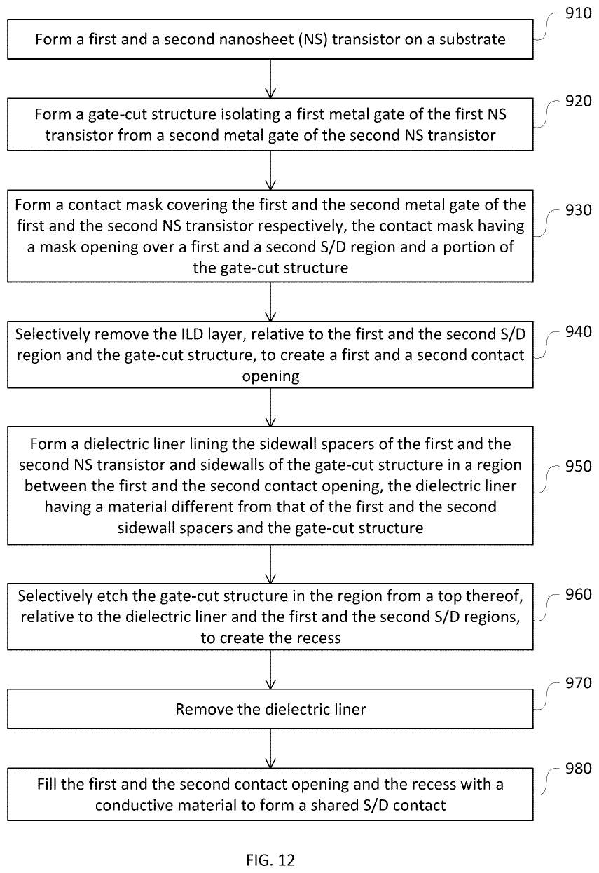

FIG. 12 is a demonstrative illustration of a flow-chart of a method of manufacturing a semiconductor structure according to embodiments of present invention. The method includes (910) forming a first and a second nanosheet (NS) transistor on a substrate; (920) forming a gate-cut structure isolating a first metal gate of the first NS transistor from a second metal gate of the second NS transistor; (930) forming a contact mask covering the first and the second metal gate of the first and the second NS transistor respectively, the contact mask having a mask opening over a first and a second S/D region and a portion of the gate-cut structure; (940) selectively removing the ILD layer, relative to the first and the second S/D region and the gate-cut structure, to create a first and a second contact opening; (950) forming a dielectric liner lining the sidewall spacers of the first and the second NS transistor and sidewalls of the gate-cut structure in a region between the first and the second contact opening, the dielectric liner having a material different from that of the first and the second sidewall spacers and the gate-cut structure; (960) selectively etching the gate-cut structure in the region from a top thereof, relative to the dielectric liner and the first and the second S/D regions, to create the recess; (970) removing the dielectric liner; and (980) filling the first and the second contact opening and the recess with a conductive material to form a shared S/D contact.

Various examples may possibly be described by one or more of the following features in the following numbered clauses:

Clause 1: A semiconductor structure comprising a first and a second nanosheet (NS) transistor on top of a semiconductor substrate; a shared source/drain (S/D) contact surrounding a first S/D region of the first NS transistor and a second S/D region of the second NS transistor; and a gate-cut structure isolating a first metal gate of the first NS transistor from a second metal gate of the second NS transistor, wherein a portion of the gate-cut structure is surrounded by the shared S/D contact at a top and sidewalls of the gate-cut structure.

Clause 2: The semiconductor structure of clause 1, wherein the portion of the gate-cut structure is horizontally between the first S/D region of the first NS transistor and the second S/D region of the second NS transistor.

Clause 3: The semiconductor structure of clause 1, wherein a first portion of the shared S/D contact at a first side of the gate-cut structure is self-aligned to a first sidewall spacer of the first metal gate of the first NS transistor, and a second portion of the shared S/D contact at a second side of the gate-cut structure is self-aligned to a second sidewall spacer of the second metal gate of the second NS transistor.

Clause 4: The semiconductor structure of clause 3, wherein a third portion of the shared S/D contact directly above the gate-cut structure is formed in a recess of the gate-cut structure and a width of the recess, in a direction along a length of the first metal gate, is wider than a width of the first portion of the shared S/D contact, in the direction along the length of the first metal gate.

Clause 5: The semiconductor structure of clause 4, wherein a bottom surface of the recess of the gate-cut structure is at a level above a top surface of the first and the second S/D region of the first and the second NS transistor.

Clause 6: The semiconductor structure of clause 3, wherein the gate-cut structure and the first and the second sidewall spacer are made of a same dielectric material of silicon-nitride (SiN).

Clause 7: The semiconductor structure of clause 1, wherein the shared S/D contact substantially surrounds the first and the second S/D region at a top and sidewalls thereof.

Clause 8: A method comprising forming a first and a second nanosheet (NS) transistor on a substrate; forming a gate-cut structure isolating a first metal gate of the first NS transistor from a second metal gate of the second NS transistor; removing an interlevel-dielectric (ILD) layer that covers a first source/drain (S/D) region of the first NS transistor and a second S/D region of the second NS transistor to create a first and a second contact opening; removing a portion of the gate-cut structure in a region between the first and the second contact opening to create a recess; and filling the first and the second contact opening and the recess with a conductive material to form a shared S/D contact.

Clause 9: The method of clause 8, wherein removing the portion of the gate-cut structure comprises forming a dielectric liner lining sidewalls of the first and the second contact opening, thereby covering a first and a second sidewall spacer of the first and the second metal gate respectively of the first and the second NS transistor, the dielectric liner covering sidewalls of the gate-cut structure in the region between the first and the second contact opening, the dielectric liner having a material that has an etch selectivity different from that of the first and the second sidewall spacer and the gate-cut structure; selectively etching the gate-cut structure in the region from a top thereof, relative to the dielectric liner and the first and the second S/D region, to create the recess; and removing the dielectric liner.

Clause 10: The method of clause 9, wherein the gate-cut structure and the sidewall spacers of the first and the second metal gate of the first and the second NS transistor are made of silicon-nitride and the dielectric liner is made of silicon-oxide.

Clause 11: The method of clause 8, wherein removing the ILD layer comprises forming a contact mask covering the first metal gate of the first NS transistor and the second metal gate of the second NS transistor, the contact mask having a mask opening over the first and the second S/D region and a portion of the gate-cut structure; and selectively removing the ILD layer, relative to the first and the second S/D region and the gate-cut structure, to create the first and the second contact opening.

Clause 12: The method of clause 11, wherein the sidewall spacers of the first and the second metal gate of the first and the second NS transistor are made of silicon-nitride, further comprising forming a capping layer of silicon-oxide on top of the first and the second metal gate of the first and the second NS transistor before forming the contact mask on top of the capping layer.

Clause 13: The method of clause 11, wherein forming the gate-cut structure comprises forming the gate-cut structure across multiple sets of NS transistors including a first set of the first and the second NS transistor and a second set of a third and a fourth NS transistor, and across a region between the first and the second S/D region of the first and the second NS transistor.

Clause 14: The method of clause 13, wherein the mask opening is wider than a length of the first S/D region of the first NS transistor, in a direction along a length of the first metal gate, and the first contact opening being self-aligned to the first sidewall spacer of the first metal gate.

Clause 15: A semiconductor structure comprising a first set of nanosheet (NS) transistors including a first and a second NS transistor; a second set of NS transistors including a third and a fourth NS transistor; a shared source/drain (S/D) contact surrounding a first S/D region of the first NS transistor and a second S/D region of the second NS transistor; and a gate-cut structure isolating a first metal gate of the first NS transistor from a second metal gate of the second NS transistor and isolating a third metal gate of the third NS transistor from a fourth metal gate of the fourth NS transistor, wherein a portion of the gate-cut structure is surrounded by the shared S/D contact at a top and sidewalls of the gate-cut structure.

Clause 16: The semiconductor structure of clause 15, wherein the portion of the gate-cut structure is horizontally between the first S/D region of the first NS transistor and the second S/D region of the second NS transistor.

Clause 17: The semiconductor structure of clause 15, wherein a first portion of the shared S/D contact at a first side of the gate-cut structure is self-aligned to a first and a third sidewall spacer of the first and the third metal gate of the first and the third NS transistor respectively; and a second portion of the shared S/D contact at a second side of the gate-cut structure is self-aligned to a second and a fourth sidewall spacer of the second and the fourth metal gate of the second and the fourth NS transistor respectively.

Clause 18: The semiconductor structure of clause 17, wherein a third portion of the shared S/D contact directly above the gate-cut structure is formed in a recess of the gate-cut structure and a width of the recess is larger than a width of the first portion of the shared S/D contact between the first and the third sidewall spacer of the first and the third NS transistor.

Clause 19: The semiconductor structure of clause 18, wherein a bottom surface of the recess of the gate-cut structure is above a top surface of the first and the second S/D region of the first and the second NS transistor.

Clause 20: The semiconductor structure of clause 17, wherein the gate-cut structure and the first and the second sidewall spacers are made of silicon-nitride (SiN).

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first and a second nanosheet (NS) transistor on top of a semiconductor substrate;
a shared source/drain (S/D) contact surrounding a first S/D region of the first NS transistor and a second S/D region of the second NS transistor; and
a gate-cut structure isolating a first metal gate of the first NS transistor from a second metal gate of the second NS transistor,
wherein a portion of the gate-cut structure is surrounded by the shared S/D contact at a top and sidewalls of the gate-cut structure.

2. The semiconductor structure of claim 1, wherein the portion of the gate-cut structure is horizontally between the first S/D region of the first NS transistor and the second S/D region of the second NS transistor.

3. The semiconductor structure of claim 1, wherein a first portion of the shared S/D contact at a first side of the gate-cut structure is self-aligned to a first sidewall spacer of the first metal gate of the first NS transistor, and a second portion of the shared S/D contact at a second side of the gate-cut structure is self-aligned to a second sidewall spacer of the second metal gate of the second NS transistor.

4. The semiconductor structure of claim 3, wherein a third portion of the shared S/D contact directly above the gate-cut structure is formed in a recess of the gate-cut structure and a width of the recess, in a direction along a length of the first metal gate, is wider than a width of the first portion of the shared S/D contact, in the direction along the length of the first metal gate.

5. The semiconductor structure of claim 4, wherein a bottom surface of the recess of the gate-cut structure is at a level above a top surface of the first and the second S/D region of the first and the second NS transistor.

6. The semiconductor structure of claim 3, wherein the gate-cut structure and the first and the second sidewall spacer are made of a same dielectric material of silicon-nitride (SiN).

7. The semiconductor structure of claim 1, wherein the shared S/D contact substantially surrounds the first and the second S/D region at a top and sidewalls thereof.

8. A method comprising:
forming a first and a second nanosheet (NS) transistor on a substrate;
forming a gate-cut structure isolating a first metal gate of the first NS transistor from a second metal gate of the second NS transistor;
removing an interlevel-dielectric (ILD) layer that covers a first source/drain (S/D) region of the first NS transistor and a second S/D region of the second NS transistor to create a first and a second contact opening;
removing a portion of the gate-cut structure in a region between the first and the second contact opening to create a recess; and
filling the first and the second contact opening and the recess with a conductive material to form a shared S/D contact.

9. The method of claim 8, wherein removing the portion of the gate-cut structure comprises:
forming a dielectric liner lining sidewalls of the first and the second contact opening, thereby covering a first and a second sidewall spacer of the first and the second metal gate respectively of the first and the second NS transistor, the dielectric liner covering sidewalls of the gate-cut structure in the region between the first and the second contact opening, the dielectric liner having a material that has an etch selectivity different from that of the first and the second sidewall spacer and the gate-cut structure;
selectively etching the gate-cut structure in the region from a top thereof, relative to the dielectric liner and the first and the second S/D region, to create the recess; and
removing the dielectric liner.

10. The method of claim 9, wherein the gate-cut structure and the sidewall spacers of the first and the second metal gate of the first and the second NS transistor are made of silicon-nitride and the dielectric liner is made of silicon-oxide.

11. The method of claim 8, wherein removing the ILD layer comprises:
forming a contact mask covering the first metal gate of the first NS transistor and the second metal gate of the second NS transistor, the contact mask having a mask opening over the first and the second S/D region and a portion of the gate-cut structure; and
selectively removing the ILD layer, relative to the first and the second S/D region and the gate-cut structure, to create the first and the second contact opening.

12. The method of claim 11, wherein the sidewall spacers of the first and the second metal gate of the first and the second NS transistor are made of silicon-nitride, further comprising forming a capping layer of silicon-oxide on top of the first and the second metal gate of the first and the second NS transistor before forming the contact mask on top of the capping layer.

13. The method of claim 11, wherein forming the gate-cut structure comprises forming the gate-cut structure across multiple sets of NS transistors including a first set of the first and the second NS transistor and a second set of a third and a fourth NS transistor, and across a region between the first and the second S/D region of the first and the second NS transistor.

14. The method of claim 13, wherein the mask opening is wider than a length of the first S/D region of the first NS transistor, in a direction along a length of the first metal gate, and the first contact opening being self-aligned to the first sidewall spacer of the first metal gate.

15. A semiconductor structure comprising:
a first set of nanosheet (NS) transistors including a first and a second NS transistor;
a second set of NS transistors including a third and a fourth NS transistor;
a shared source/drain (S/D) contact surrounding a first S/D region of the first NS transistor and a second S/D region of the second NS transistor; and
a gate-cut structure isolating a first metal gate of the first NS transistor from a second metal gate of the second NS transistor and isolating a third metal gate of the third NS transistor from a fourth metal gate of the fourth NS transistor,
wherein a portion of the gate-cut structure is surrounded by the shared S/D contact at a top and sidewalls of the gate-cut structure.

16. The semiconductor structure of claim 15, wherein the portion of the gate-cut structure is horizontally between the first S/D region of the first NS transistor and the second S/D region of the second NS transistor.

17. The semiconductor structure of claim 15, wherein a first portion of the shared S/D contact at a first side of the gate-cut structure is self-aligned to a first and a third sidewall spacer of the first and the third metal gate of the first and the third NS transistor respectively; and a second portion of the shared S/D contact at a second side of the gate-cut structure is self-aligned to a second and a fourth sidewall spacer of the second and the fourth metal gate of the second and the fourth NS transistor respectively.

18. The semiconductor structure of claim 17, wherein a third portion of the shared S/D contact directly above the gate-cut structure is formed in a recess of the gate-cut structure and a width of the recess is larger than a width of the first portion of the shared S/D contact between the first and the third sidewall spacer of the first and the third NS transistor.

19. The semiconductor structure of claim 18, wherein a bottom surface of the recess of the gate-cut structure is above a top surface of the first and the second S/D region of the first and the second NS transistor.

20. The semiconductor structure of claim 17, wherein the gate-cut structure and the first and the second sidewall spacers are made of silicon-nitride (SiN).
